(19) United States
(12) Patent Application Publication
(10) Pub. No.: US 2025/0359370 A1
(43) Pub. Date: Nov. 20, 2025

(54) SOLID-STATE IMAGING DEVICE PACKAGE

(71) Applicant: KANEKA CORPORATION, Osaka (JP)

(72) Inventors: Makoto Kutsumizu, Osaka (JP); Rina Takeda, Osaka (JP)

(73) Assignee: KANEKA CORPORATION, Osaka (JP)

(21) Appl. No.: 19/289,762

(22) Filed: Aug. 4, 2025

Related U.S. Application Data
(63) Continuation of application No. PCT/JP2024/001578, filed on Jan. 22, 2024.

(30) Foreign Application Priority Data
Feb. 8, 2023 (JP) 2023-017390

(51) Int. Cl. H10F 39/00

(52) U.S. Cl. CPC H10F 39/804

(57) ABSTRACT

A solid-state imaging device package, which provides a captured image with little noise, includes a transparent substrate, a frame-form wall body that defines an inner-side space, and a solid-state imaging device that captures an image of light incident in the inner-side space through the transparent substrate. The wall body is formed from a colorant-containing resin composition and is stacked on one main surface of the transparent substrate. The arithmetic average surface roughness Ra of an inner peripheral surface of the wall body is 50-3000 nm inclusive. The shortest distance between the wall body and a function unit of the solid-state imaging device is 800 μm or less.

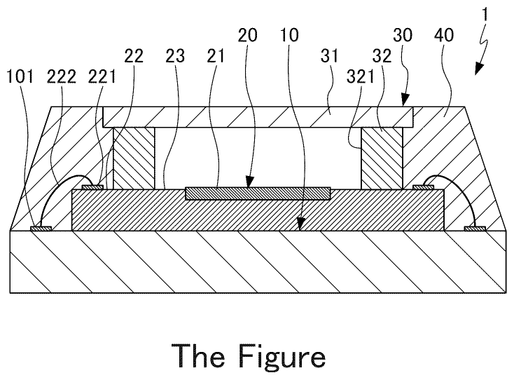

### TECHNICAL FIELD

One or more embodiments of the present invention relate to a solid-state imaging device package.

### BACKGROUND

A solid-state imaging device package in which a wall (frame) surrounding a solid-state image element is bonded to a substrate on which a solid-state imaging device is mounted, and an opening of the wall is covered with a transparent substrate such as a glass plate is widely used (for example, see Patent Document 1). In such a solid-state imaging device package, the wall determines the relative position of the transparent substrate with respect to the solid-state imaging device, and suppresses unintended light from being incident on the solid-state imaging device, thereby reducing noise such as flare and ghost of a captured image.

### PATENT DOCUMENT

Patent Document 1: Japanese Unexamined Patent Application, Publication No. 2004-296453

The demand for miniaturization of solid-state imaging device packages has been increasing, and solid-state imaging device packages configured by glass on chip or the like in which a wall is bonded to an outer peripheral portion of a solid-state imaging device have also increased. When the solid-state imaging device package is miniaturized, high accuracy is required for the wall. In order to improve the accuracy of the wall, it is conceivable to prepare an optical substrate in which the wall is directly formed on a transparent substrate, and bond the wall of the optical substrate to the solid-state imaging device or a mounting substrate on which the solid-state imaging device is mounted.

As a method of molding a resin on a transparent substrate with high accuracy, a photolithography technique is known. However, since it is necessary to use a material having a light shielding property in order to form a wall capable of restricting the incidence of light as described above, development (selective curing or solubilization of a resin) by light cannot be performed. In addition, when the content of the pigment is increased, the pigment remains in the opening portion to be removed during development, which causes an image noise. Therefore, it has been studied to form the wall with a resin containing a minimum amount of pigment, but when the content of the pigment is reduced, noise of the captured image such as flare and ghost is likely to increase. In view of the above circumstances, one or more embodiments of the present invention are to provide a solid-state imaging device package with less noise in a captured image.

### SUMMARY

A solid-state imaging device package according to one aspect of one or more embodiments of the present invention includes a transparent substrate, a wall shaped in a frame-form formed of a resin composition containing a coloring agent, and a solid-state imaging device. The wall is laminated on one main surface of the transparent substrate and defines an inner space. The solid-state imaging device captures an image of light incident on the inner space through the transparent substrate. An arithmetic average roughness Ra of an inner peripheral surface of the wall is 50 nm or more and 3000 nm or less, and a shortest distance between the wall and a functional unit of the solid-state imaging device is 800 μm or less.

In the solid-state imaging device package, the content of the coloring agent may be 5% by mass or less.

In the solid-state imaging device package, the skewness Ssk of the inner peripheral surface of the wall may be negative.

In the solid-state imaging device package, the wall may be bonded to the solid-state imaging device.

In the solid-state imaging device package, the wall may be formed of a photocurable resin composition.

According to one or more embodiments of the present invention, it is possible to provide a solid-state imaging device package with less noise in a captured image.

### BRIEF DESCRIPTION OF THE DRAWING

The FIGURE is a cross-sectional view of a solid-state imaging device package according to one or more embodiments of the present invention.

### DETAILED DESCRIPTION

Hereinafter, one or more embodiments of the present invention will be described with reference to the drawings. In the following embodiments, the same components as those in the preceding embodiment are denoted by the same reference numerals, and redundant description may be omitted. In the drawings, changes in proportions, omission of details, and the like may be made in order to make features easy to understand.

The FIGURE is a cross-sectional view of a solid-state imaging device package 1 according to one or more embodiments of the present invention. The solid-state imaging device package 1 includes a mounting substrate 10, a solid-state imaging device 20 mounted on the mounting substrate 10, an optical substrate 30 bonded to the solid-state imaging device 20, and a sealing material 40 that seals the outside of the solid-state imaging device 20 and the optical substrate 30 on the mounting substrate 10.

The mounting substrate 10 is a structural member that supports the solid-state imaging device 20. Therefore, the mounting substrate 10 is formed of a material having sufficient rigidity. The mounting substrate 10 may be a simple support, but may be a circuit board on which a circuit for supplying power to the solid-state imaging device 20 and extracting a signal from the solid-state imaging device 20 is formed. In one or more embodiments, the mounting substrate 10 has a circuit including an electrode 101 for electrical connection to the solid-state imaging device 20.

Examples of the mounting substrate 10 include organic substances such as polyimides, polyesters, ceramics, epoxy resins, bismaleimide triazine, and phenol resins, structures obtained by impregnating paper, glass fiber nonwoven fabric, or the like with the organic substances and thermally curing the organic substances, ceramics such as alumina, aluminum nitride, beryllium oxide, and silicon nitride, and metal substrates. Among them, a glass epoxy substrate and a ceramic substrate are preferred. A circuit having a metal wiring pattern or a metal bump may be formed on the surface or inside of these insulating substrates.

The solid-state imaging device 20 is mounted on the mounting substrate 10 on a side opposite to the optical substrate 30. The solid-state imaging device 20 is formed on a surface facing the optical substrate 30, and has a functional unit 21 for performing imaging, a connection portion 22 for performing electrical connection, and a margin portion 23 between the functional unit 21 and the connection portion 22. The solid-state imaging device 20 is mounted such that the imaging surface of the functional unit 21 is parallel to the main surface of the mounting substrate 10, in other words, such that the optical axis is parallel to the normal direction of the mounting substrate 10. As the solid-state imaging device 20, for example, a two-dimensional imaging device such as a CMOS image sensor can be used. As the functional unit 21, a two-dimensional imaging device structure such as a CMOS image sensor can be formed. The connection portion 22 is a region where an electrode 221 and the like for electrically connecting the solid-state imaging device 20 to the mounting substrate 10 and the like are provided. As in one or more embodiments, the connection portion 22 may be provided outside the functional unit 21. The connection portion 22 may be provided on a surface opposite to the functional unit 21, in other words, a surface facing the mounting substrate 10. In one or more embodiments, the electrode 221 of the solid-state imaging device 20 and the electrode 101 of the mounting substrate 10 are electrically connected to each other via a wire 222. The margin portion 23 is a region to which the optical substrate 30 is bonded.

The optical substrate 30 forms a sealed space in which the functional unit 21 is sealed on the solid-state imaging device 20. The optical substrate 30 includes a transparent substrate 31 and a frame-shaped wall 32 that is laminated on one main surface of the transparent substrate 31 and bonded to the margin portion 23 to define an inner space in which the functional unit 21 is disposed. In other words, in the solid-state imaging device package 1, the solid-state imaging device 20 captures an image of light incident on the inner space through the transparent substrate 31.

The transparent substrate 31 is a transparent plate material. The transparent substrate 31 may be formed of transparent ceramics such as glass or sapphire, or transparent plastics such as an acrylic resin or polycarbonate, but may be formed of transparent ceramics from the viewpoint of reliability, or may be formed of glass from the viewpoint of versatility. The type of glass forming the transparent substrate 31 is not particularly limited, and examples thereof include quartz glass, borosilicate glass, and alkali-free glass.

The wall 32 is formed of a resin composition containing a coloring agent, and may be formed of a photocurable resin composition. By forming the wall 32 from the photocurable resin composition, the wall 32 having a uniform thickness and an accurate planar shape can be formed by, for example, a photolithography technique or the like. The photocurable resin composition contains, for example, a resin component having a reactive group such as an epoxy group or an acrylic group, and a photopolymerization initiator. Examples of the coloring agent contained in the photocurable resin composition include organic pigments, inorganic pigments, and dyes. From the viewpoint of heat resistance and colorability, a pigment may be used as the coloring agent. In the case of forming a black colored pattern, a black pigment may be used as the coloring agent. Examples of colored patterns other than black patterns include red patterns, yellow patterns, and blue patterns.

As the pigment, a pigment that widely absorbs wavelengths in the visible light region is preferable. Among pigments that widely absorb wavelengths in the visible light region, examples of black organic pigments include anthraquinone-based black pigments, perylene-based black pigments, azo-based black pigments, and lactam-based black pigments. Among these, perylene-based black pigments and lactam-based black pigments are preferable from the viewpoint of excellent light-shielding properties. Examples of black inorganic pigments include carbon black and black titanium sub-oxynitride. Examples of other inorganic pigments include carbon black, composite metal oxide pigments, titanium oxide, barium sulfate, lead sulfate, chrome yellow, red iron oxide, ultramarine blue, Prussian blue, chromium oxide, antimony white, zinc sulfide, zinc, manganese violet, cobalt violet, magnesium carbonate, and the like. Examples of the dye include azo-based compounds, anthraquinone-based compounds, perylene-based compounds, perinone-based compounds, phthalocyanine-based compounds, carbonium-based compounds, and indigoid-based compounds. Examples of the pigment for obtaining a colored pattern other than a black pattern include color pigments such as red, orange, yellow, green, cyan, violet, cyanine, and magenta.

Specific examples of the color pigments include Color Index (C. I.) Pigment Yellow 1, 10, 83, etc.; C. I. Pigment Orange 2, 5, 13, etc.; C. I. Pigment Red 1, 2, 3, etc.; C. I. Pigment Green 7, 10, 36, etc.; and C. I. Pigment Blue 1, 2, 15, etc. These pigments may be used alone or in combination of two or more.

The lower limit of the content of the coloring agent in the photocurable resin composition to form the wall 32 may be 0.2% by mass, 0.5% by mass, or 0.8% by mass. On the other hand, the upper limit of the content of the coloring agent in the photocurable resin composition to form the wall 32 may be 5% by mass, 4% by mass, or 3% by mass. By setting the content of the coloring agent to be equal to or more than the lower limit, the light transmittance of the wall 32 can be reduced, and thus flare and ghost can be effectively suppressed. In addition, by setting the content of the coloring agent to the upper limit or less, even the inside of the photocurable resin composition can be exposed to form the wall 32 having an accurate shape, and it is also possible to suppress the coloring agent from remaining on the surface of the transparent substrate 31 after the photocurable resin composition in the region not irradiated with light is removed.

The lower limit of the shortest distance between the wall 32 and the functional unit 21 of the solid-state imaging device 20 may be 100 μm, or 200 μm. On the other hand, the upper limit of the shortest distance between the wall 32 and the functional unit 21 may be 800 μm, or 600 μm. By setting the shortest distance between the wall 32 and the functional unit 21 to be equal to or more than the lower limit, it is possible to prevent the wall 32 from being reflected in the captured image and prevent the light reflected by an inner peripheral surface 321 from being incident on the functional unit 21. In addition, by setting the shortest distance between the wall 32 and the functional unit 21 to be equal to or less than the upper limit, it is possible to block unintended light that may be obliquely incident on the functional unit 21.

The wall 32 has an uneven structure that scatters light at least on the inner peripheral surface 321 exposed to the inner space. The inner peripheral surface 321 having the uneven structure diffuses light to reduce the intensity of unintended light incident on the functional unit 21 of the solid-state imaging device 20, and increases the S/N ratio to suppress visible flare and ghost. In particular, even when the content of the coloring agent is reduced as described above, the wall 32 scatters the transmitted light on the inner peripheral surface 321, and thus the image noise can be sufficiently suppressed. Further, for example, even when unintended light incident on the inner space of the solid-state imaging device package 1, such as light obliquely incident on the inner space of the wall 32, is reflected and incident on the wall 32, the inner peripheral surface 321 diffuses light that may be re-reflected by the wall 32 and incident on the functional unit 21 of the solid-state imaging device 20, thereby suppressing image noise. In order to further reduce the reflection of obliquely incident light, the inner peripheral surface 321 of the wall 32 may be formed in a tapered shape or a dome shape such that the inner diameter on the transparent substrate 31 side is small.

The uneven structure of the inner peripheral surface 321 can be formed by, for example, embossing in which a mold having unevenness is pressed against the surface in a state where the wall 32 is in a semi-cured state (B stage). When the wall 32 is cured in a state where the mounting substrate 10 is brought into close contact with the wall 32 in the semi-cured state in which the inner peripheral surface 321 is formed, the wall 32 can be bonded to the margin portion 23 of the solid-state imaging device 20 without using an adhesive.

The lower limit of the arithmetic average roughness Ra (JIS-B0601) of the inner peripheral surface 321 may be 50 nm, 100 nm, or 200 nm. On the other hand, the upper limit of the arithmetic average roughness Ra of the inner peripheral surface 321 may be 3000 nm, 2600 nm, 2000 nm, or 1000 nm. By setting the arithmetic average roughness Ra of the inner peripheral surface 321 to be equal to or more than the lower limit, specular reflection can be more effectively suppressed, and thus flare and ghost can be more effectively suppressed. In addition, by setting the arithmetic average roughness Ra of the inner peripheral surface 321 to be equal to or less than the upper limit, the manufacturing is relatively easy, and thus the manufacturing cost can be suppressed.

The lower limit of the average length RSm (JIS-B0601) of the roughness curve element of the inner peripheral surface 321 may be 100 nm, 200 nm, or 300 nm. On the other hand, the upper limit of the average length RSm of the roughness curve element of the inner peripheral surface 321 may be 20000 nm, 10000 nm, or 8000 nm. When the average length RSm of the roughness curve element of the inner peripheral surface 321 is set to be equal to or more than the lower limit, the manufacturing is relatively easy, and thus the manufacturing cost can be suppressed. In addition, by setting the average length RSm of the roughness curve element of the inner peripheral surface 321 to be equal to or less than the upper limit, specular reflection can be more effectively suppressed, and thus flare and ghost can be more effectively suppressed.

The skewness Ssk (ISO 25178) of the inner peripheral surface 321 may be a negative value. More specifically, the lower limit of the skewness Ssk of the inner peripheral surface 321 may be −0.80, or −0.70, and the upper limit of the skewness Ssk of the inner peripheral surface 321 may be −0.10, or −0.20. When the skewness Ssk is equal to or more than the lower limit, the unevenness is easily miniaturized, and thus flare and ghost can be effectively suppressed. In addition, by setting the skewness Ssk to be equal to or less than the upper limit, the light incident on the inner peripheral surface 321 is repeatedly reflected at the valley portions of the unevenness and attenuated, and is reflected so as to be dispersed in a plurality of directions. Thus, it is possible to reduce the specular reflection, and thus, it is possible to promote the effect of suppressing flare and ghost.

The sealing material 40 seals the outside of the solid-state imaging device 20 and the optical substrate 30 on the mounting substrate 10, thereby preventing the optical substrate 30 from being peeled off from the solid-state imaging device 20 by an external object. The sealing material 40 protects the wire 222 and ensures electrical connection between the mounting substrate 10 and the solid-state imaging device 20.

The sealing material 40 may be a thermosetting resin such as an epoxy resin, an acrylic resin, or a silicone resin, or may be an epoxy resin from the viewpoint of toughness and heat resistance. In addition, in order to prevent unintended light from being incident on the functional unit 21, the sealing material 40 may be formed of a resin composition containing a coloring agent or a light diffusing material. The sealing material 40 may contain a filler such as silica that has thixotropy before curing in order to facilitate formation.

The solid-state imaging device package 1 having the above-described configuration includes the optical substrate 30 capable of suppressing flare and ghost by the inner peripheral surface 321 even when the content of the coloring agent is reduced to such an extent that the wall 32 can be formed by, for example, photolithography without leaving a residue on the transparent substrate 31, and thus can capture a high-quality image with less noise.

Although one or more embodiments of the present invention have been described above, the present invention is not limited to the above-described embodiments, and various changes and modifications can be made. The solid-state imaging device package according to one or more embodiments of the present invention may be, for example, a so-called chip size package in which the planar size of entire of the solid-state imaging device package and the planar size of the optical substrate are substantially equal to the planar size of the solid-state imaging device. The wall may be bonded to a mounting substrate on which a solid-state imaging device having a functional unit formed on substantially the entire surface is to be mounted.

### EXAMPLES

Hereinafter, one or more embodiments of the present invention are specifically described based on Examples, but are not limited to the following Examples.

A test sample of a solid-state imaging device package having the structure shown in the FIGURE was produced and its performance was evaluated. Specifically, a photocurable resin composition for forming a wall was prepared, and the composition was applied onto a glass substrate, and walls in a semi-cured state having different distances (wall distances) from the functional unit of the solid-state imaging device were formed by photolithography. Various optical substrates were produced by an embossing process in which templates having a plurality of types of shapes of unevenness were pressed against the inner peripheries of the walls in the semi-cured state. These optical substrates were bonded to mounting substrates on each of which a solid-state imaging device was mounted, and thereby trial products 1 to 18 of solid-state imaging device packages were produced. Note that a test sample18 was not embossed. The wall distances of these trial products are collectively shown in Table 1.

In the preparation of the photocurable resin composition, first, 143 μL of a xylene solution of a platinum-vinylsiloxane complex (“Pt-VTSC-3X” manufactured by Umicore Precious Metals Japan, a solution containing 3% by mass of platinum) was added to a mixture of 40 g of diallyl isocyanurate, 29 g of diallyl monomethyl isocyanurate, and 264 g of 1,4-dioxane to obtain a solution S1. Separately, 88 g of 1,3,5,7-tetrahydrogen-1,3,5,7-tetramethylcyclotetrasiloxane was dissolved in 176 g of toluene to obtain a solution S2.

Thereafter, in a nitrogen atmosphere containing 3% by volume of oxygen, the solution S1 was added dropwise to the solution S2 over 3 hours in a state where the solution S2 was heated to a temperature of 105 C. After completion of the dropwise addition, the obtained solution was stirred for 30 minutes while maintaining the temperature at 105 C, to thereby obtain a solution S3. Separately, 62 g of 1-vinyl-3,4-epoxycyclohexane was dissolved in 62 g of toluene to obtain a solution S4. Then, in a nitrogen atmosphere containing 3% by volume of oxygen, the solution S4 was added dropwise to the solution S3 over 1 hour in a state where the solution S3 was heated to a temperature of 105 C. After the completion of the dropwise addition, the obtained solution was stirred for 30 minutes while the temperature was maintained at 105 C, to thereby obtain a solution S5.

After cooling the solution S5, solvents (toluene, xylene, and 1,4-dioxane) were distilled off from the solution S5 under reduced pressure to obtain a solid content. Next, 49 parts by mass of propylene glycol 1-monomethyl ether 2-acetate, 15 parts by mass of an epoxy monomer (3′,4′-epoxycyclohexylmethyl 3,4-epoxycyclohexanecarboxylate: “CELLOXIDE 2021P” manufactured by Daicel Corporation), 1 part by mass of a sulfonium salt-based photo-cationic polymerization initiator (“CPI-210S” manufactured by San-Apro Co., Ltd.), and a black organic pigment (“NPFT-70565”) were added to 100 parts by mass of the obtained solid content (see Table 1 for the amounts of the black organic pigment blended) to obtain a photocurable resin composition for forming the wall. The light transmittance of the photocurable resin composition at a wavelength of 600 nm was 4% in the case of blending 2 parts by mass of the black organic pigment.

The arithmetic average roughness Ra (evaluation length: 20 μm) and the skewness Ssk of the inner peripheral surface of the wall formed on the glass substrate were measured using a 3D measurement laser microscope “LEXT-OLS 5100” manufactured by Olympus Corporation. The skewness Ssk was obtained by randomly selecting 10 measurement points (20 μm×20 μm square regions) and averaging the measured values of the skewness Ssk at the selected measurement points (see Table 1).

The performance of the solid-state imaging device package was evaluated by the number of residues on the transparent substrate inside the wall, the ghost index of the captured image, and the reflection in the captured image. The number of residues was determined by observing a 1 mm square area of the transparent substrate using a 3D measurement laser microscope “LEXT-OLS 4000” manufactured by Olympus Corporation, and the case where 10 or more residues/foreign substances having a size of 10 μm or more were present was evaluated as D, the case where 6 to 9 residues/foreign substances were present was evaluated as C, the case where 3 to 5 residues/foreign substances were present was evaluated as B, and the case where 2 or less residues/foreign substances were present was evaluated as A. The ghost index was obtained by the following method: the number of abnormal pixels exceeding a predetermined threshold value (one one hundred millionth with respect to the luminance of the light source) was obtained by using a ghost flare evaluation system “GCS-2T” manufactured by Tsubosaka Electric Co., Ltd., and then a percentage of a value (number of abnormal pixels/total number of pixels) obtained by dividing the number of abnormal pixels by the total number of pixels with respect to that of a non-embossed test sample17 was calculated (see Table 1). The reflection was evaluated by capturing images of ten trial products of solid-state imaging device packages having the same specifications, and evaluating the case where the number of solid-state imaging device packages for which the reflection was confirmed was 0 as A, the case where the number of solid-state imaging device packages was 1 or more and 4 or less as B, and the case where the number of solid-state imaging device packages was 5 or more as C.

TABLE 1

| Test | Pigment | | Wall | | | Ghosting | |
|---|---|---|---|---|---|---|---|
| sample | [parts by | Ra | distance | | | Index | Reflec- |
| Number | mass] | [nm] | [nm] | Ssk | Ssk | [%] | tion |
| 1 | 2 | 450 | 1000 | 0.1 | A | 92 | A |
| 2 | 2 | 450 | 700 | 0.1 | A | 77 | A |
| 3 | 2 | 450 | 300 | 0.1 | A | 63 | A |
| 4 | 2 | 450 | 200 | 0.1 | A | 75 | B |
| 5 | 2 | 450 | 100 | 0.1 | A | 85 | C |
| 6 | 2 | 200 | 500 | 0. | A | 81 | A |
| 7 | 2 | 350 | 500 | 0.1 | A | 75 | A |
| 8 | 2 | 450 | 500 | 0.1 | A | 65 | A |
| 9 | 2 | 500 | 500 | 0.1 | A | 67 | A |
| 10 | 2 | 850 | 500 | 0.1 | A | 76 | A |
| 11 | 2 | 1000 | 500 | 0.1 | A | 85 | A |
| 12 | 2 | 1500 | 500 | 0. | A | 86 | A |
| 13 | 2 | 2500 | 500 | 0.1 | A | 86 | A |
| 14 | 5 | 450 | 500 | 0.1 | A | 65 | A |
| 15 | 8 | 450 | 500 | 0.1 | B | 64 | A |
| 16 | 10 | 450 | 500 | 0.1 | C | 63 | A |
| 17 | 2 | 450 | 500 | −0.35 | A | 60 | A |
| 18 | 0 | 30 | 500 | 0.02 | A | 100 | A |

As described above, it was confirmed that, when the arithmetic average roughness Ra is set to 50 nm or more and 3000 nm or less and the wall distance is set to 100 μm or more and 800 μm or less, it was possible to reduce the residue, the ghost index, and the reflection in the optical path, in other words, it was possible to improve the image quality, only by adding a relatively small amount of the pigment.

### EXPLANATION OF REFERENCE NUMERALS

1 SOLID-STATE IMAGING DEVICE PACKAGE
10 MOUNTING SUBSTRATE
20 SOLID-STATE IMAGING DEVICE
21 FUNCTIONAL UNIT
22 CONNECTION PORTION
23 MARGIN PORTION
30 OPTICAL SUBSTRATE
31 TRANSPARENT SUBSTRATE
32 WALL
321 INNER PERIPHERAL SURFACE
40 SEALING MATERIAL

Although the disclosure has been described with respect to only a limited number of embodiments, those skilled in the art, having benefit of this disclosure, will appreciate that various other embodiments may be devised without departing from the scope of the present disclosure. Accordingly, the scope of the invention should be limited only by the attached claims.

1. A solid-state imaging device package comprising:
a transparent substrate;
a wall shaped in a frame-form that is formed of a resin composition comprising a coloring agent, and is laminated on one main surface of the transparent substrate to define an inner space, and
a solid-state imaging device that captures an image of light incident into the inner space through the transparent substrate,
wherein:
an arithmetic average roughness Ra of an inner peripheral surface of the wall is 50 nm or more and 3000 nm or less, and
a shortest distance between the wall and a functional portion of the solid-state imaging device is 800 μm or less.

2. The solid-state imaging device package according to claim 1, wherein a content of the coloring agent is 5 mass % or less.

3. The solid-state imaging device package according to claim 1, wherein a skewness Ssk of the inner peripheral surface of the wall is a negative value.

4. The solid-state imaging device package according to claim 1, wherein the wall is bonded to the solid-state imaging device.

5. The solid-state imaging device package according to claim 1, wherein the wall is formed of a resin composition having photocurability.
